(19) United States
(12) Patent Application Publication
(10) Pub. No.: US 2023/0009720 A1
(43) Pub. Date: Jan. 12, 2023

(54) FILM FORMING METHOD AND HEAT TREATMENT APPARATUS

(71) Applicant: Tokyo Electron Limited, Tokyo (JP)

(72) Inventors: Yasuaki KIKUCHI, Iwate (JP); Tsubasa YOKOI, Yamanashi (JP); Tatsuya YAMAGUCHI, Iwate (JP); Keisuke SUZUKI, Yamanashi (JP)

(21) Appl. No.: 17/857,914

(22) Filed: Jul. 5, 2022

(30) Foreign Application Priority Data
Jul. 8, 2021 (JP) 2021-113349

(51) Int. Cl. C23C 16/06; H01L 21/285; C23C 16/52

(52) U.S. Cl. CPC C23C 16/06; H01L 21/28506; C23C 16/52

(57) ABSTRACT

A method of forming a film is performed in a heat treatment apparatus that includes a processing container, a tubular member provided in the processing container, a heater configured to heat an inside of the processing container, and a gas supply. The method includes: providing a substrate in the tubular member; adjusting a temperature inside the tubular member by the heater; and after adjusting the temperature, supplying a gas containing a film-forming gas from the gas supply into the processing container to form a film on the substrate. In the adjusting the temperature, a gas containing a heat transfer gas is supplied from the gas supply into the processing container.

### CROSS-REFERENCE TO RELATED APPLICATION

This application is based on and claims priority from Japanese Patent Application No. 2021-113349 filed on Jul. 8, 2021 with the Japan Patent Office, the disclosure of which is incorporated herein in its entirety by reference.

### TECHNICAL FIELD

The present disclosure relates to a film forming method and a heat treatment apparatus.

### BACKGROUND

A technique has been proposed to measure the temperature inside the processing container of a semiconductor manufacturing apparatus and use the measurement results for controlling the process conditions of a substrate process executed in the processing container (see, e.g., Japanese Patent Laid-Open Publication No. 2004-172409).

### SUMMARY

According to an aspect of the present disclosure, a method of forming a film is performed in a heat treatment apparatus that includes a processing container, a tubular member provided in the processing container, a heater configured to heat an inside of the processing container, and a gas supply. The method includes: providing a substrate in the tubular member; adjusting a temperature inside the tubular member by the heater; and after the adjusting the temperature, supplying a gas containing a film-forming gas from the gas supply into the processing container, thereby forming a film on the substrate. In the adjusting the temperature, a gas containing a heat transfer gas is supplied from the gas supply into the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a heat treatment apparatus according to an embodiment.

FIGS. 2A to 2C are views illustrating a problem of overheating in a processing container.

FIG. 3 is a view illustrating an example of a functional configuration of a control device according to the embodiment.

FIG. 4 is a view illustrating an example of a hardware configuration of the control device according to the embodiment.

FIGS. 5A to 5D are views illustrating the effect of supplying a heat transfer gas according to the embodiment.

FIG. 6 is a flowchart illustrating an example of a film forming method according to the embodiment.

FIGS. 7A to 7F are views illustrating an example of the effect of supplying the heat transfer gas by the film forming method according to the embodiment.

FIG. 8 is a flowchart illustrating an example of details of the film forming process of FIG. 6.

FIGS. 9A and 9B are views illustrating an example of the effect of supplying the heat transfer gas by the film forming method according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the accompanying drawings. In each of the drawings, the same components may be designated by the same reference numerals and duplicate descriptions thereof may be omitted.

[Heat Treatment Apparatus]

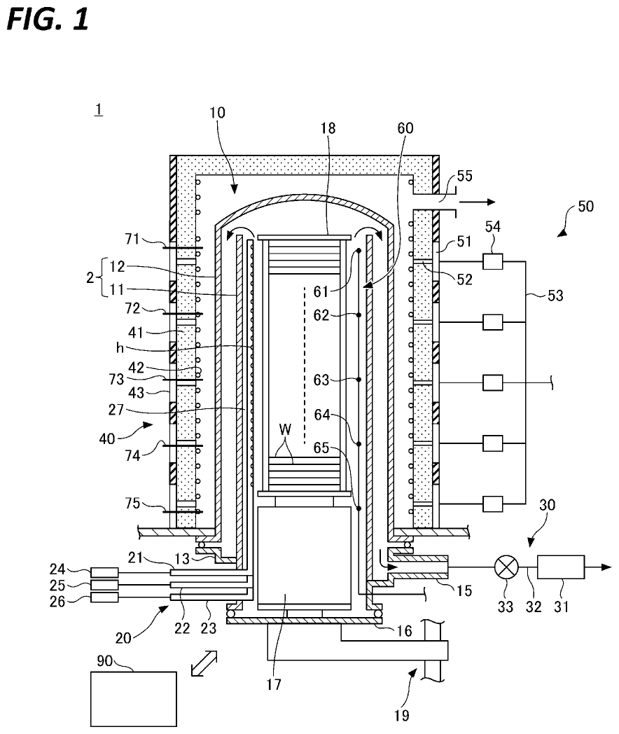

A heat treatment apparatus 1 of an embodiment will be described with reference to FIG. 1. FIG. 1 is a schematic view illustrating an example of the heat treatment apparatus 1 according to the embodiment.

The heat treatment apparatus 1 includes a processing container 10 and a tubular member 2. The processing container 10 has a substantially cylindrical shape. The tubular member 2 is disposed inside the processing container 10 and includes an inner pipe 11 and an outer pipe 12. The inner pipe 11 has a substantially cylindrical shape. The inner pipe 11 is made of a heat-resistant material such as quartz. The inner pipe 11 accommodates a substrate W. The inner pipe 11 may also be referred to as an inner tube.

The outer pipe 12 has a substantially cylindrical shape with a ceiling, and is provided concentrically around the inner pipe 11. The outer pipe 12 is made of a heat-resistant material such as quartz. The outer pipe 12 is also referred to as an outer tube. The heat treatment apparatus 1 has a double structure of a tubular member 2 and a processing container 10.

The heat treatment apparatus 1 includes a manifold 13, gas supply pipes 21, 22, 23, a gas outlet 15, and a cover 16. The manifold 13 has a substantially cylindrical shape. The manifold 13 supports the lower ends of the inner pipe 11 and the outer pipe 12. The manifold 13 is made of, for example, stainless steel.

A gas supply unit 20 is provided in the manifold 13 and introduces a gas into the inner pipe 11. The gas supply unit 20 includes a plurality (three in the illustrated example) of gas pipes 21, 22, and 23 made of quartz. Each of the gas pipes 21, 22, and 23 extends in the inner pipe 11 along the longitudinal direction thereof, and is supported such that the base end of each gas pipe is bent in an L shape and penetrates the manifold 13.

The gas supply pipes 21, 22, and 23 are provided in a nozzle accommodating portion 27 of the inner pipe 11 to be aligned in a circumferential direction. Each of the gas supply pipes 21, 22, and 23 includes a plurality of gas holes h formed at predetermined intervals along the longitudinal direction. Each of the gas holes h discharges each gas in the horizontal direction. The predetermined interval is set to be the same as, for example, the interval between the substrates W supported on a wafer boat 18. Further, the position in the height direction is set such that each of the gas holes h is located in the middle between vertically adjacent substrates W, and each gas may be efficiently supplied to the space between the substrates W. Gas supply sources 24, 25, and 26 are connected to the gas supply pipes 21, 22, and 23 via flow rate controllers and valves, respectively. The gas supply sources 24, 25, and 26 are supply sources for a film-forming gas, a cleaning gas, and a heat transfer gas, respectively. The flow rate of each gas from the gas supply sources 24, 25, and 26 is controlled by the flow rate controller, and is supplied into the processing container 10 via the gas supply pipes 21, 22, and 23 as needed.

In the present embodiment, the film-forming gas is a gas used for forming a metal film such as a molybdenum (Mo) film. In the example of FIG. 1, a case has been illustrated where the gas supply pipes 21, 22, and 23 are disposed one by one, but the number of the gas supply pipes 21, 22, and 23 may be plural.

The gas outlet 15 is formed in the manifold 13. An exhaust pipe 32 is connected to the gas outlet 15. The processing gas supplied into the processing container 10 is exhausted by the exhaust unit 30 via the gas outlet 15.

The cover 16 airtightly closes the opening at the lower end of the manifold 13. The cover 16 is made of, for example, stainless steel. The wafer boat 18 is disposed on the cover 16 via a heat insulating cylinder 17. The heat insulating cylinder 17 and the wafer boat 18 are made of a heat-resistant material such as quartz. The wafer boat 18 holds a plurality of substrates W substantially horizontally at predetermined intervals in the vertical direction. When an elevating unit 19 raises the cover 16, the wafer boat 18 is loaded into the processing container 10 and accommodated in the processing container 10. When the elevating unit 19 lowers the cover 16, the wafer boat 18 is unloaded from the processing container 10. An example of the substrate W is a wafer.

The heat treatment apparatus 1 includes an exhaust unit 30, a heating unit 40, a cooling unit 50, and a control device 90. The exhaust unit 30 includes an exhaust apparatus 31, an exhaust pipe 32, and a pressure controller 33. The exhaust apparatus 31 is a vacuum pump such as a dry pump or a turbo molecular pump. The exhaust pipe 32 connects the gas outlet 15 and the exhaust apparatus 31. The pressure controller 33 is interposed in the exhaust pipe 32, and controls the pressure in the processing container 10 by adjusting the conductance of the exhaust pipe 32. The pressure controller 33 is, for example, an automatic pressure control valve.

The heating unit 40 includes a heat insulating material 41, a heater 42, and an outer skin 43. The heat insulating material 41 has a substantially cylindrical shape and is provided around the outer pipe 12. The heat insulating material 41 is formed mainly of silica and alumina. The heater 42 is an example of a heating element and is provided on the inner circumference of the heat insulating material 41. The heater 42 is provided linearly or planarly on the side wall of the processing container 10 such that the temperature may be controlled by dividing the heater 42 into a plurality of zones in the height direction of the processing container 10. The outer skin 43 is provided to cover the outer periphery of the heat insulating material 41. The outer skin 43 keeps the shape of the heat insulating material 41 and reinforces the heat insulating material 41. The outer skin 43 is made of a metal such as stainless steel. Further, in order to suppress the influence of heat on the outside of the heating unit 40, a water-cooled jacket (not illustrated) may be provided on the outer periphery of the outer skin 43. In the heating unit 40, the calorific value of the heater 42 is determined by the power supplied to the heater 42, whereby the inside of the processing container 10 is heated to a desired temperature.

The cooling unit 50 supplies air toward the processing container 10 and cools the substrate W in the processing container 10. Air is an example of a cooling fluid. The cooling unit 50 supplies air toward the processing container 10, for example, when the substrate W is rapidly lowered in temperature after heat treatment. The cooling unit 50 includes a fluid flow path 51, a blowout hole 52, a distribution flow path 53, a flow rate adjusting unit 54, and a heat exhaust port 55.

A plurality of fluid flow paths 51 is formed in the height direction between the heat insulating material 41 and the outer skin 43. The fluid flow path 51 is, for example, a flow path formed along the circumferential direction on the outside of the heat insulating material 41.

The blowout hole 52 is formed to penetrate the heat insulating material 41 from each fluid flow path 51, and discharges air into the space between the outer pipe 12 and the heat insulating material 41.

The distribution flow path 53 is provided outside the outer skin 43, and distributes and supplies air to each fluid flow path 51. The flow rate adjusting unit 54 is interposed in the distribution flow path 53, and adjusts the flow rate of the air supplied to the fluid flow path 51.

The heat exhaust port 55 is provided above the plurality of blowout holes 52, and discharges the air supplied to the space between the outer pipe 12 and the heat insulating material 41 to the outside of the heat treatment apparatus 1. The air discharged to the outside of the heat treatment apparatus 1 is cooled by, for example, a heat exchanger and supplied to the distribution flow path 53 again. However, the air discharged to the outside of the heat treatment apparatus 1 may be discharged without being reused.

A temperature sensor 60 detects the temperature inside the tubular member 2. The temperature sensor 60 is provided in, for example, the inner pipe 11. However, the temperature sensor 60 may be provided at a position where the temperature inside the tubular member 2 is detectable, and may be provided, for example, in the space between the inner pipe 11 and the outer pipe 12. The temperature sensor 60 includes, for example, a plurality of temperature measuring units 61 to 65 provided at different positions in the height direction corresponding to a plurality of zones. The temperature measuring units 61 to 65 are provided corresponding to the zones of “TOP,” “C-T,” “CTR,” “C-B,” and “BTM,” respectively. The plurality of temperature measuring units 61 to 65 may be, for example, a thermocouple or a temperature measuring resistor. The temperature sensor 60 transmits the temperatures detected by the plurality of temperature measuring units 61 to 65 to the control device 90.

The temperature sensors 71 to 75 (hereinafter, also collectively referred to as a “temperature sensor 70”) are inserted into the space between the processing container 10 and the tubular member 2 from the outside of the processing container 10. As a result, the temperature measuring units of the temperature sensor 70 are disposed at substantially the same height as the temperature measuring units 61 to 65 corresponding to the zones of “TOP,” “C-T,” “CTR,” “C-B,” and “BTM.” Each of the temperature measuring units of the temperature sensor 70 may be, for example, a thermocouple or a temperature measuring resistor. The temperature sensor 70 transmits the temperatures detected by the plurality of temperature measuring units to the control device 90.

The number of the temperature measuring units of the temperature sensors 60 and 70 is not limited to five, and may be seven or one or more. There is a temperature sensor 70 near the heater 42, and the heater 42 and the temperature measuring units of the temperature sensor 70 and the temperature sensor 60 are paired. The temperature inside the tubular member 2 measured by the temperature sensor 60 is also referred to as an “inner temperature.” The temperature outside the tubular member 2 measured by the temperature sensor 70 and inside the processing container 10 is also referred to as an “outer temperature.”

The control device 90 controls the operation of the heat treatment apparatus 1. The control device 90 may be, for example, a computer. A computer program that performs the entire operation of the heat treatment apparatus 1 is stored in a storage medium. The storage medium may be, for example, a flexible disk, a compact disk, a hard disk, a flash memory, or a DVD.

[Overheating of Outer Temperature]

In general, in the heat treatment apparatus 1, the temperature (inner temperature) of the region inside the tubular member 2 (hereinafter, also referred to as an “inner region”) is raised to a target temperature set in a recipe, and a desired film forming process is performed on the substrate W. At this time, heat is transferred from the outer region to the inner region by controlling the power of the heater 42 provided in the region outside the tubular member 2 and inside the processing container 10 (hereinafter, also referred to as an “outer region”), and the inner temperature is raised to the target temperature. In the present specification, the target temperature is the target temperature in the inner region subjected to temperature control.

However, in a case where a metal film having a high reflectance such as a molybdenum film is formed on the substrate W by the heat treatment apparatus 1, when the molybdenum film is formed, the molybdenum film of the tubular member 2 (the surface of the inner pipe 11 and the inner surface of the outer pipe 12) is attached. Since the reflectance of the molybdenum film is as high as about 0.97, the molybdenum film attached to the inside of the tubular member 2 functions as a reflective film. When the surface of the inner pipe 11 and the inner surface of the outer pipe 12 are covered with a highly reflective film, the heat insulating effect due to the double structure of the tubular member 2 is enhanced, and it takes time to transfer heat from the outer region to the inner region.

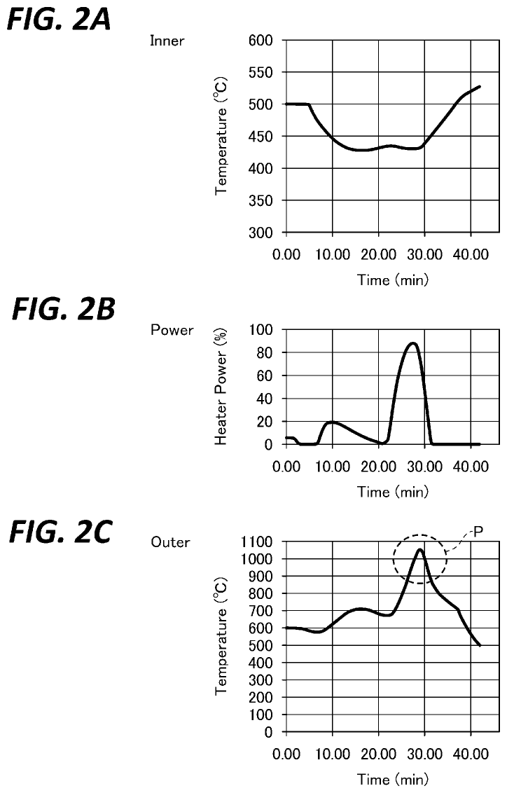

FIGS. 2A to 2C are graphs illustrating a problem of overheating in a processing container 10. FIG. 2A is a graph illustrating an example of the inner temperature in which the horizontal axis indicates the time and the vertical axis indicates the temperature. The inner temperature is gradually increased by controlling the power of the heater 42 illustrated in FIG. 2B.

However, the molybdenum film attached to the inside of the tubular member 2 functions as a reflective film, and due to the double structure of the tubular member 2, it takes time to transfer heat from the outer region to the inner region. Thus, even when the power of the heater 42 is increased, the inner temperature does not rise immediately. Therefore, the power of the heater 42 is further increased. In the example of FIG. 2B, the power of the heater 42 may be further increased when the time is less than 30 minutes.

As a result, the state in which the outer temperature exceeds a preset excess temperature is illustrated in “P” of FIG. 2C. FIG. 2C is a graph illustrating an example of the inner temperature in which the horizontal axis indicates the time and the vertical axis indicates the temperature. The outer temperature exceeds the excess temperature (1050° C.) in less than 30 minutes due to the increase in the power of the heater 42. When the excess temperature is exceeded, the heater 42 is shut down and the heating by the heater 42 is stopped due to safety problems.

In order to avoid the overheating of the outer temperature described above, it is conceivable to control the power of the heater 42 to slowly raise the inner temperature. Then, although the outer temperature does not exceed the excess temperature, it takes time for the inner temperature to rise to the target temperature, and the productivity decreases. In consideration of productivity, it is important to control the inner temperature to the target temperature as soon as possible while avoiding overheating.

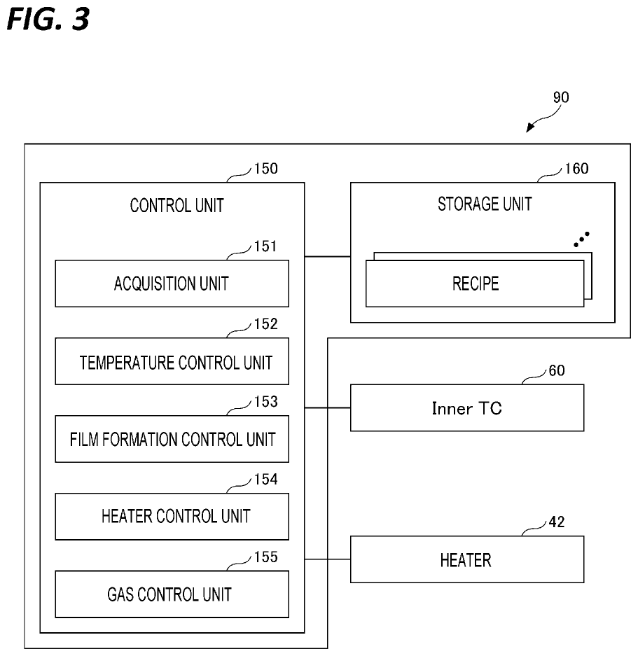

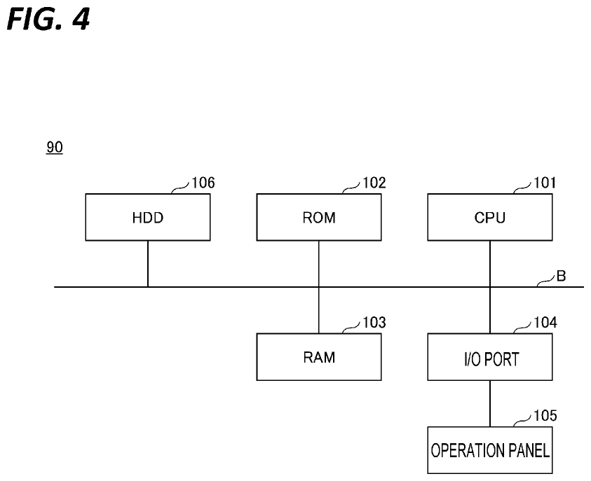

Therefore, the present disclosure proposes a film forming method capable of shortening the time for controlling the inner temperature to the target temperature. The film forming method according to the embodiment is controlled by the control device 90 and performed by the heat treatment apparatus 1. Hereinafter, the functional configuration and the hardware configuration of the control device 90 will be described with reference to FIGS. 3 and 4, and then the film forming method according to the embodiment will be described. FIG. 3 is a view illustrating an example of the functional configuration of the control device 90 according to the embodiment. FIG. 4 is a view illustrating an example of the hardware configuration of the control device 90 according to the embodiment. In the following description, an example of forming a molybdenum film in the film forming method according to the embodiment will be described.

The control device 90 includes a control unit 150 and a storage unit 160. The storage unit 160 stores a recipe in which a procedure for forming a molybdenum film on the substrate W is set. In the recipe, process conditions such as a gas type, a gas flow rate, a pressure, a temperature, and a processing time are set for one or a plurality of steps.

The control unit 150 includes an acquisition unit 151, a temperature control unit 152, a film formation control unit 153, a heater control unit 154, and a gas control unit 155. The acquisition unit 151 acquires the inner temperature from the temperature sensor 60 (inner TC).

The temperature control unit 152 controls the inner region to reach the target temperature based on the acquired inner temperature. The heater control unit 154 controls the power of the heater 42, and as a result, the temperature control unit 152 adjusts the inner temperature. The film formation control unit 153 forms a molybdenum film on the substrate W according to the process conditions set in the recipe. The gas control unit 155 supplies a film forming gas and a cleaning gas. Further, the gas control unit 155 supplies the heat transfer gas when performing a temperature control such as a temperature stabilization of the inner region, a temperature raise, and a temperature decrease.

An example of the hardware configuration of the control device 90 will be described with reference to FIG. 4. The control device 90 includes a central processing unit (CPU) 101, a read only memory (ROM) 102, a random access memory (RAM) 103, an I/O port 104, an operation panel 105, and a hard disk drive (HDD) 106. Each unit is connected by a bus B.

The CPU 101 controls various operations of the heat treatment apparatus 1, a film forming process, and a cleaning process based on various programs read into RAM 103 and recipes which define procedures for processes such as the film forming process and the cleaning process. The programs include a program for executing the film forming method according to the embodiment. The CPU 101 performs the film forming method according to the embodiment based on the programs read into the RAM 103.

The ROM 102 is a storage medium that is constituted by an electrically erasable programmable read-only memory (EEPROM), a flash memory, or a hard disk, and stores a program or a recipe of the CPU 101. The RAM 103 functions as a work area of the CPU 101.

The I/O port 104 acquires the values of various sensors for detecting a temperature, a pressure, and a gas flow rate from various sensors attached to the heat treatment apparatus 1 and transmits the values to the CPU 101. Further, the I/O port 104 outputs a control signal output by the CPU 101 to each part of the heat treatment apparatus 1. An operation panel 105 for operating the heat treatment apparatus 1 by an operator (user) is connected to the I/O port 104.

The HDD 106 is an auxiliary storage device and may store recipes and programs. Also, the HDD 106 may store log information of measurement values measured by various sensors.

The storage unit 160 may be implemented by any one of the ROM 102, RAM 103, EEPROM, flash memory, and HDD 106. The acquisition unit 151 may be implemented by the I/O port 104. The temperature control unit 152, the film formation control unit 153, the heater control unit 154, and the gas control unit 155 may be implemented by the CPU 101.

[Improved Temperature Controllability]

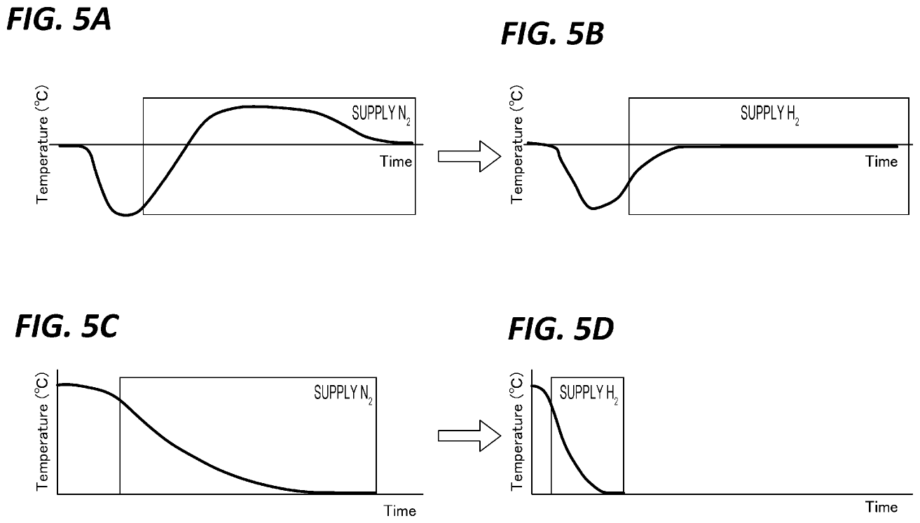

Next, with reference to FIGS. 5A to 5D, a method for improving temperature controllability by H₂ gas according to the embodiment will be described in comparison with a reference example. FIGS. 5A and 5C illustrate the temperature control by N₂ gas of the reference example. FIGS. 5B and 5C illustrate the temperature control by H₂ gas of the embodiment. FIGS. 5A to 5D illustrate the time until the temperature in the inner region reaches the target temperature. FIG. 5A illustrates a case where N₂ gas is supplied from the gas supply unit 20 into the processing container 10 and controlled such that the inner region reaches the target temperature based on the inner temperature acquired from the temperature sensor 60. In this case, undershoot and overshoot occur before the temperature stabilizes at the target temperature.

FIG. 5B illustrates a case where H₂ gas is supplied from the gas supply unit 20 into the processing container 10 and controlled such that the inner region reaches the target temperature based on the inner temperature acquired from the temperature sensor 60. In this case, the target temperature is controlled after the undershoot occurs. As a result, overshoot may be suppressed and the time to reach the target temperature may be shortened.

FIG. 5C illustrates a case where the temperature of the inner region is lowered to the target temperature while N₂ gas is supplied from the gas supply unit 20 into the processing container 10. FIG. 5D illustrates a case where the temperature of the inner region is lowered to the target temperature while H₂ gas is supplied from the gas supply unit 20 into the processing container 10. As a result, when the H₂ gas illustrated in FIG. 5D is supplied, the temperature lowering time may be shortened to about ¼ as compared with the case where the N₂ gas illustrated in FIG. 5C is supplied.

The thermal conductivity of H₂ gas at 500° C. is 267 mW/(m·K). The thermal conductivity of N₂ gas at 500° C. is 38.64 mW/(m·K). The thermal conductivity of H₂ gas is about 7 times that of N₂ gas. By supplying a gas having a high thermal conductivity such as H₂ gas into the processing container 10 in this way, the thermal conductivity may be significantly improved, and the temperature adjustment (temperature stabilization) time in the inner region may be significantly shortened.

[Film Forming Method]

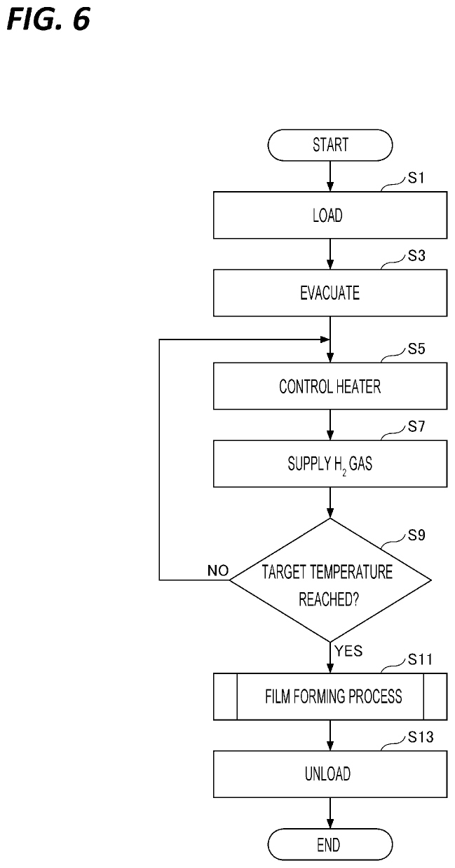

Next, a film forming method including temperature adjustment according to the embodiment will be described by taking as an example a case where a film is formed on a substrate by using the heat treatment apparatus 1. FIG. 6 is a flow-chart illustrating an example of the film forming method according to the embodiment.

First, the wafer boat 18 holding a plurality of substrates W is raised by the elevating unit 19 and loaded into a loading area, the opening of the lower end of the processing container 10 is airtightly sealed by the lid 16, and the substrate W is prepared (step S1). Next, the inside of the processing container 10 is evacuated (step S3).

In step S1, the opening at the lower end of the processing container 10 is opened, and the substrate W having a relatively low temperature is loaded into the loading area, so that the temperature in the inner region is lowered. The heater control unit 154 controls the power of the heater 42 based on the detected temperatures of the temperature measuring units 61 to 65 of the temperature sensor 60 such that the lowered temperature in the processing container 10 is maintained at a set temperature (e.g., 300° C. to 700° C.) determined in advance by a recipe, whereby the temperature control unit 152 adjusts the temperature in the inner region to the target temperature (step S5). The gas control unit 155 supplies H₂ gas into the processing container 10. Further, steps S5 and S7 may be performed at the same time, or step S5 may be started after step S7 is started.

Next, the temperature control unit 152 determines whether the temperature in the inner region has reached the target temperature (step S9). When it is determined that the target temperature has not been reached, the temperature control unit 152 returns to step S5 and repeats steps S5 to S9 until the target temperature is reached. When it is determined in step S9 that the target temperature has been reached, the temperature control unit 152 determines that the temperature in the inner region has stabilized and completes the temperature adjustment, and the film formation control unit 153 executes the film formation process of the molybdenum film (step S11).

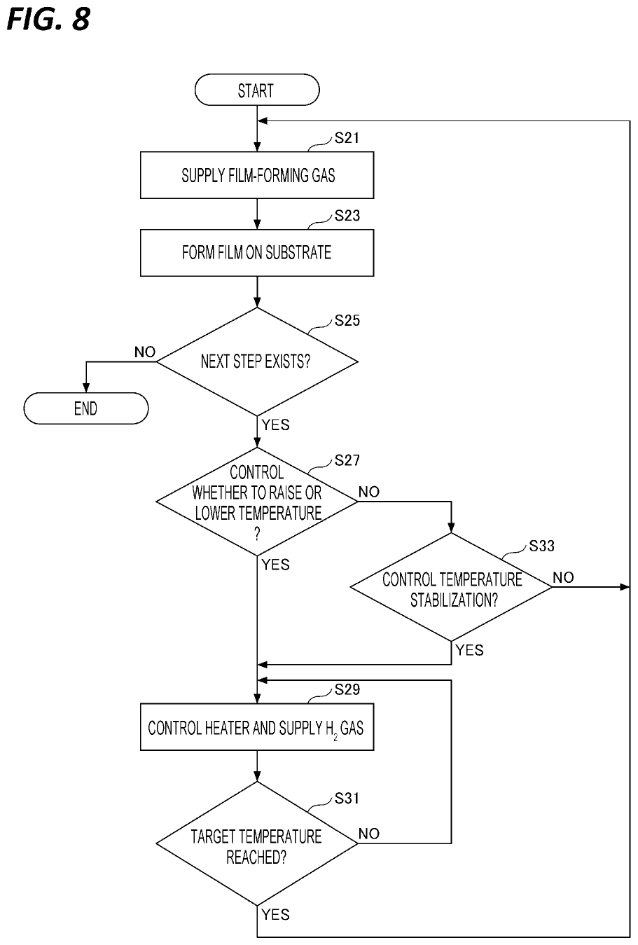

An example of the film forming process in step S11 will be described later with reference to the flow-chart of FIG. 8. After the film forming process in step S11, the wafer boat 18 holding the plurality of substrates W is carried out (unloaded) out of the processing container 10 by the elevating unit 19, and this process is completed (step S13).

The film forming method according to the present embodiment has been described above. The film forming method according to the present embodiment includes steps of preparing the substrate in the processing container, adjusting the temperature in the processing container by the heating unit, adjusting the temperature and then supplying a gas from the gas supply unit into the processing container, and forming the film on the substrate. In the step of adjusting the temperature, a gas containing a heat transfer gas is supplied from the gas supply unit into the processing container. As a result, the heat transfer effect may be enhanced and the temperature controllability may be improved by supplying the heat transfer gas at the time of temperature adjustment.

[Example of Effects]

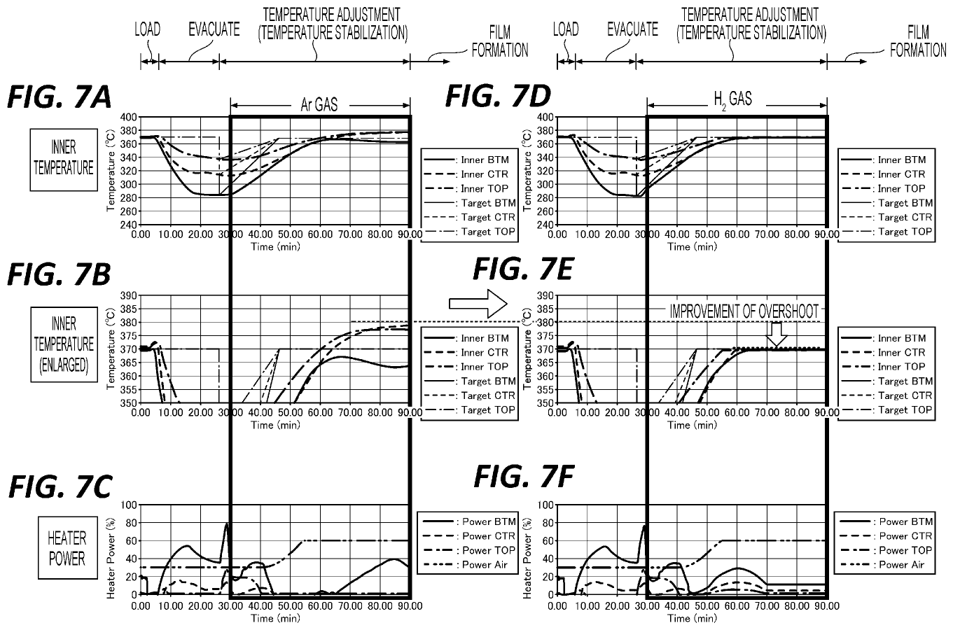

An example of the effect of the film forming method according to the embodiment described above will be described with reference to FIGS. 7A to 7F. FIGS. 7A to 7F are views illustrating an example of the effect of supplying the heat transfer gas by the film forming method according to the embodiment.

FIGS. 7A to 7C represent reference examples. FIGS. 7A to 7C illustrate the temperature (vertical axis) detected by the temperature measuring units 61, 63, and 65 of the temperature sensor 60 with respect to the time (horizontal axis) when Ar gas is supplied into the processing container during the temperature adjustment process in the flow of loading→evacuation→temperature adjustment (temperature stabilization)→film formation. FIGS. 7D to 7F represent the present embodiment. FIG. 7F illustrates the temperature (vertical axis) detected by the temperature measuring units 61, 63, and 65 of the temperature sensor 60 with respect to the time (horizontal axis) when H₂ gas is supplied into the processing container during the temperature adjustment process in the flow of loading→evacuation→temperature adjustment (temperature stabilization)→film formation.

In FIGS. 7A to 7F, the target temperatures of the zones “TOP,” “CTR,” and “BTM” are indicated by “Target TOP,” “Target CTR,” and “Target BTM,” respectively. The target temperatures may be set to the same temperature or different temperatures. In the examples of FIGS. 7A to 7F, “Target TOP,” “Target CTR,” and “Target BTM” are 370° C.

The temperature of the inner region of each zone is indicated by “Inner TOP,” “Inner CTR,” and “Inner BTM.” Further, the power of the heater 42 in each zone is indicated by “Power TOP,” “Power CTR,” and “Power BTM.” The output of air is indicated by “Power Air.”

Referring to FIGS. 7A and 7D, since the wafer boat 18 is loaded into the loading area from the start of loading (0 minutes) to about 6 minutes, the temperature of the inner region drops at the temperature of, for example, 100 loaded substrates W. Therefore, the detection temperature measured by the temperature sensor 60 (temperature measuring units 61, 63, and 65) drops.

As illustrated in FIGS. 7C and 7F, the output of the heater in each zone indicated by “Power CTR” and “Power BTM” increases from about 6 minutes, the heater of “Power TOP” is output later, and the inner region is controlled to raise the temperature. However, exhaust (evacuation) by the exhaust unit 30 is started from about 6 minutes, and the inside of the processing container 10 becomes a decompressed atmosphere, so that heat conduction deteriorates. Air is output from the start of process as indicated by “Power Air.” Air has the effect of promoting temperature adjustment and exhaust of Ar gas or H₂ gas. However, air may or may not be supplied.

In about 26 minutes, the output of the heater in each zone rapidly increases and the temperature stops decreasing, and then the temperature in each zone begins to rise due to the temperature adjustment to the target temperature in each zone. In FIGS. 7A to 7F, the supply of Ar gas or H₂ gas starts from about 30 minutes.

In the temperature control of the reference example, as illustrated in FIG. 7C, the output of the heater of “Power BTM” becomes larger during the temperature adjustment (temperature stabilization), and the power of the heater 42 of “Power TOP” and “Power CTR” is hardly output. This is because the heat is not easily transferred from the outer region to the inner region, so that the output of the heater of the “Power BTM” becomes larger. As a result, as illustrated in an enlarged manner in FIG. 7B, overshoot occurs and the temperature of the inner region of the center and the top exceeds the target temperature.

In the temperature control of the embodiment, as illustrated in FIG. 7F, the power of the heater 42 of “Power TOP,” “Power CTRM,” and “Power BTM” is output during the temperature adjustment (temperature stabilization). It is considered that this is because the heat transfer effect from the outer region to the inner region is enhanced by the H₂ gas, so that the power of the heater 42 in each zone is normally output. As a result, as illustrated in an enlarged manner in FIG. 7E, overshoot does not occur, and the temperature of the inner region of each zone does not exceed the target temperature of each zone. From the above-mentioned results, in the film forming method according to the embodiment, the temperature controllability may be improved and the time for temperature stabilization may be shortened.

[Film Forming Process]

Next, the details of the film forming process executed in step S11 of FIG. 6 will be described with reference to FIG. 8. FIG. 8 is a flowchart illustrating an example of details of the film forming process of FIG. 6. In the film forming process, the gas supply unit 20 stops supplying the H₂ gas and supplies the film-forming gas (step S21).

Next, the film formation control unit 153 forms a molybdenum film on the substrate W based on the recipe (step S23). Next, the film formation control unit 153 determines whether there is a next step (step S25), and when it is determined that there is a next step, the temperature control unit 152 determines whether to control the temperature rise or drop in the inner region before the film formation in the next step is performed (step S27). In step S27, when it is determined that the inner region is controlled to raise or lower the temperature, the temperature control unit 152 controls the power of the heater 42 based on the detected temperatures of the temperature measuring units 61 to 65 of the temperature sensor 60, and supplies H₂ gas (step S29).

Next, the temperature control unit 152 determines whether the target temperature has been reached (step S31), and when it is determined that the target temperature has not been reached, the temperature control unit 152 returns to step S29 and repeats steps S29 to S31 until the target temperature is reached. When it is determined that the target temperature has been reached, the temperature control unit 152 returns to step S21 and forms a film on the substrate W in steps S21 to S23.

In step S27, when it is determined that the inner region is not controlled to raise or lower the temperature, the temperature control unit 152 determines whether to control the temperature stabilization of the inner region (step S33). In step S33, when it is determined that the temperature stabilization in the inner region is controlled, the temperature control unit 152 controls the power of the heater 42 based on the detected temperatures of the temperature measuring units 61 to 65 of the temperature sensor 60, and supplies H₂ gas (step S29). Next, the temperature control unit 152 determines whether the target temperature has been reached (step S31), and when it is determined that the target temperature has not been reached, the temperature control unit 152 returns to step S29 and repeats steps S29 to S31 until the target temperature is reached. When it is determined that the target temperature has been reached, the temperature control unit 152 returns to step S21 and forms a film on the substrate W in steps S21 to S23.

When it is determined in step S31 that the temperature stabilization in the inner region is not controlled, the temperature control unit 152 returns to step S21 and forms a film on the substrate W in steps S21 to S23. When it is determined in step S25 that there is no next step, this process ends.

Descriptions have been made above regarding the film forming method according to the present embodiment. In the film forming method according to the present embodiment, when a process of forming the substrate W has a plurality of steps, and when it is determined that the process includes a step of determining whether a step of adjusting the temperature is provided before the execution of each step and a step of adjusting the temperature in the determination step, the gas containing the heat transfer gas is supplied for a predetermined time in the step of adjusting the temperature. In the step of adjusting the temperature, the temperature controllability may be improved by supplying a gas containing a heat transfer gas not only during the temperature stabilization in the inner region but also during the temperature rise or drop in the inner region.

[Example of Effects]

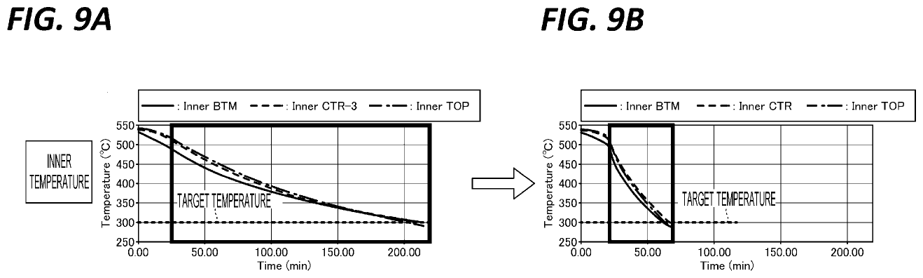

An example of the effect of the film forming method according to the above-mentioned embodiment will be described with reference to FIGS. 9A and 9B. FIGS. 9A and 9B are views illustrating an example of the effect of supplying the heat transfer gas by the film forming method according to the embodiment.

FIG. 9A represents a reference example, and FIG. 9B represents the present embodiment. FIG. 9A illustrates the temperature (vertical axis) detected by the temperature measuring units 61, 63, and 65 of the temperature sensor 60 with respect to time (horizontal axis) when Ar gas is supplied into the processing container during the process of controlling the temperature of the inner region to the target temperature. FIG. 9B illustrates the temperature (vertical axis) detected by the temperature measuring units 61, 63, and 65 of the temperature sensor 60 with respect to time (horizontal axis) when H₂ gas is supplied into the processing container during the process of controlling the temperature of the inner region to the target temperature.

Accordingly, when H₂ gas is supplied at the time of temperature decrease in each of the zones of “Inner TOP,” “Inner CTR,” and “Inner BTM,” the time may be shortened by about 150 minutes to reach the target temperature compared with the case where Ar gas is supplied at the time of temperature decrease. That is, since the heat transfer effect of H₂ gas is enhanced, the temperature adjustment time may be shortened to about ¼ in this example.

The same effect may be obtained for raising the temperature. As a result, the temperature of the inner region may be raised or lowered to the target temperature in a relatively short time. For example, by supplying a heat transfer gas such as H₂ gas at the timing when the temperature stabilization, temperature rise, and temperature decrease are performed in the inner region before and between steps during film formation, it is possible to increase the transfer efficiency with which the heat transfer gas transfers the heat of the heater 42 from the outer region to the inner region. As a result, it is possible to improve temperature controllability such as shortening the temperature adjustment time accompanying the improvement of the heat transfer effect.

The heat transfer gas is not limited to H₂ gas, and a gas having a high thermal conductivity such as He may also be used. The heat transfer gas may be only a gas having a high thermal conductivity such as H₂ gas or He, or may be a mixed gas containing other gases.

In the above-mentioned embodiment, descriptions have been made on the film forming method by the chemical vapor deposition (CVD) method as an example of the film forming method. However, the present disclosure is not limited thereto and is, for example, applicable to the atomic layer deposition (ALD).

For example, in the film forming method by the ALD method, H₂ gas, a film-forming gas (e.g., a reaction gas), H₂ gas, and a film-forming gas (e.g., a reduction gas) are alternately supplied in this order during the film formation. As a result, the temperature adjustment time before film formation with the film-forming gas may be shortened.

The film forming method according to the embodiment is not limited to the molybdenum film, and a metal film such as a tungsten film or a niobium film may be formed. Alternatively, a film other than the metal film may be formed.

According to an aspect of the present disclosure, temperature controllability may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film forming method in a heat treatment apparatus, the method comprising:
providing a substrate in a tube that is provided in a processing container of the heat treatment apparatus;
adjusting a temperature inside the tube by a heater that is provided to heat an inside of the processing container; and
after the adjusting the temperature, supplying a gas containing a film-forming gas from a gas supply into the processing container, thereby forming a film on the substrate,
wherein in the adjusting the temperature, a gas containing a heat transfer gas is supplied from the gas supply into the processing container.

2. The film forming method according to claim 1, wherein the adjusting the temperature includes supplying a gas containing the heat transfer gas in at least one of a temperature stabilization, a temperature rise, and a temperature decrease in the tube.

3. The film forming method according to claim 1, wherein the gas containing the heat transfer gas is supplied to the tube at a predetermined time before the formation of the film on the substrate, or before a subsequent formation of the film on the substrate.

4. The film forming method according to claim 3, wherein, when the formation of the film on the substrate is performed a plurality of times, the gas containing the heat transfer gas is supplied to the tube for a predetermined time in the adjusting the temperature for each time when the formation of the film on the substrate is performed.

5. The film forming method according to claim 1, wherein the heat transfer gas contains at least one of H₂ gas and He gas.

6. The film forming method according to claim 1, wherein in the formation of the film on the substrate, a metal film is formed on the substrate.

7. The film forming method according to claim 1, wherein the gas containing the heat transfer gas is supplied in the adjusting the temperature after the inside of the processing container is evacuated.

8. The film forming method according to claim 1, wherein air and the gas containing the heat transfer gas are supplied into the processing container in the adjusting the temperature.

9. A heat treatment apparatus comprising:
a processing container;
a tube in the processing container;
a heater configured to heat an inside of the processing container;
a gas supply; and
a controller,
wherein the controller is configured to execute a process including:
providing a substrate in the tube;
adjusting a temperature inside the tube by the heater; and
after the adjusting the temperature, supplying a gas containing a film-forming gas from the gas supply into the processing container, thereby forming a film on the substrate,
wherein in the adjusting the temperature, a gas containing a heat transfer gas is supplied from the gas supply into the processing container.
